(19) United States
(12) Patent Application Publication
(10) Pub. No.: US 2007/0269749 A1
(43) Pub. Date: Nov. 22, 2007

(54) Methods to reduce the minimum pitch in a pattern

(76) Inventor: Richard Elliot Schenker, Portland, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/437,159

(22) Filed: May 18, 2006

(51) Int. Cl. G03F 7/26

(52) U.S. Cl. 430/322

(57) ABSTRACT

Methods to reduce the minimum pitch of a pattern are described. A photo-resist on a substrate is exposed to a radiation through a mask. The mask has features that are separated by a distance. Photo-resist portions having a first exposure to the radiation, second exposure to the radiation, and third exposure to the radiation are created. The photo-resist portions having the first exposure to the radiation are selectively removed from the substrate using a first chemistry. The second photo-resist portions having the second exposure to the radiation are selectively removed from the substrate using a second chemistry. The photo-resist portions having the third exposure to the radiation remain to form a pattern on the substrate. The distance between features of the pattern is at least twice smaller than the distance between the features of the mask.

### FIELD

Embodiments of the invention relate generally to the field of microelectronic device manufacturing. More specifically, embodiments of the invention relate to methods of reducing a pitch of a pattern created on a microelectronic substrate.

### BACKGROUND

The microelectronic device industry uses various lithography techniques to create patterns that define microelectronic devices and circuits onto a microelectronic substrate. These lithography techniques are used for patterning a light sensitive material (“photo-resist”) deposited on a microelectronic substrate (e.g., a semiconductor substrate). The light transmitted through a mask containing a pattern illuminates the photo-resist. Typically, for a positive tone photo-resist, the regions of the photo-resist that have been exposed to the light are removed during a developing process, while regions of the photo-resist that have not been exposed to light, remain on the substrate. For a negative tone photo-resist, the regions of the photo-resist that have not been exposed to light are removed during a developing process, while regions of the photo-resist that have been exposed to light, remain on the substrate. That is, the selective light sensitivity of the photo-resist material enables one to transfer the patterns from the mask to the substrate. Typically, the minimum distance (“pitch”) between the center of features of patterns transferred from the mask to the substrate by a lithography system defines the patterning resolution.

Generally, the minimum pitch of patterns transferred from the mask to the substrate even with the use of such resolution enhancements, as phase-shift masks and off-axis illumination, is proportional to the ratio of the wavelength of the light divided by the effective Numerical Aperture of the patterning tool used for the lithography. It is generally accepted that the minimum half-pitch (“Lₘᵢₙ”), which is physically achievable using existing lithography tools is the following:

Lₘᵢₙ=0.25λ/NA (1)

where λ is the wavelength of the light, and NA is the effective numerical aperture of the patterning tool. One way to decrease the minimum pitch and to print ever smaller features of the patterns is to use the shorter exposure wavelengths to project image of a pattern onto the substrate. For example, Extreme Ultraviolet lithography (“EUVL”) is one of the lithography technologies, which employs the radiation (“light”) having short wavelengths in the approximate range of 10 nanometers (“nm”) to 14 nm that enables to print features having a size smaller than 100 nm. Another way to decrease the minimum pitch and to print ever smaller features of the patterns is to use the patterning tools having higher effective numerical aperture.

FIGS. 1A-1B show a typical lithographic patterning using a positive tone photo-resist. As shown in FIG. 1A, a positive tone photo-resist 102 is deposited on a substrate 101. Photo-resist 102 is exposed to the light 107 through a mask 103. Mask 103 has clear portions 104 and opaque features 108 that form a pattern, as shown in FIG. 1A. A distance (pitch) 109 between opaque features 108 is shown in FIG. 1A. Clear portions 104 transmit light 107 to photo-resist 102. Opaque features 108 prevent light 107 from being transmitted to photo-resist 102. FIG. 1A shows photo-resist 102 having portions 105 that are exposed to light 107 and portions 106 that are not exposed to light 107. As shown in FIG. 1A, mask features 108 are imaged onto the photo-resist 102 to produce corresponding photo-resist features 106.

FIG. 1B is a view similar to FIG. 1A, after removing exposed portions 105 of positive tone photo-resist 102. As shown in FIG. 1B, unexposed portions 106 remain on substrate 101 and form the pattern transferred from mask 103 to substrate 101. As shown in FIGS. 1A-1B, mask features 108 are imaged onto photo-resist 102 to produce a corresponding photo-resist feature (portions 106). As shown in FIGS. 1A-1B, pitch 110 between portions 106 is determined by pitch 109 between features 108 of mask 103.

FIGS. 2A-2B show a typical lithographic patterning using a negative tone photo-resist 202. As shown in FIG. 2A, a negative tone photo-resist 202 is deposited on a substrate 201. Photo-resist 202 is exposed to the light 207 through a mask 203. Mask 203 has clear features 204 that form a pattern and opaque portions 208, as shown in FIG. 2A. A distance (pitch) 209 between clear features 204 is shown in FIG. 2A. Clear features 204 transmit light 207 to photo-resist 202. Opaque portions 208 prevent light 207 from being transmitted to photo-resist 202. FIG. 2A shows photo-resist 202 having portions 205 that are exposed to light 207 and portions 206 that are not exposed to light 207. As shown in FIG. 1A, mask features 204 are imaged onto the photo-resist 202 to produce corresponding photo-resist features 205.

FIG. 2B is a view similar to FIG. 2A, after removing unexposed portions 206 of negative tone photo-resist 202. As shown in FIG. 2B, unexposed portions 206 remain on substrate 201 and form a pattern transferred from mask 203 to substrate 201. As shown in FIGS. 2A-2B, mask features 204 are imaged onto photo-resist 202 to produce a corresponding photo-resist feature (portions 205). Pitch 210 between portions 205 is determined by pitch 209 between features 204 of mask 203, as shown in FIGS. 2A-2B.

### BRIEF DESCRIPTION OF THE DRAWINGS

FIG. 1A, shows a lithographic patterning using a positive tone photo-resist;

FIG. 1B is a view similar to FIG. 1A, after removing exposed portions of positive tone photo-resist;

FIG. 2A shows a typical lithographic patterning using a negative tone photo-resist;

FIG. 2B is a view similar to FIG. 2A, after removing unexposed portions of negative tone photo-resist;

FIG. 3 shows a pattern transferred from a mask onto a substrate according to one embodiment of the invention;

FIG. 4A shows a photo-resist deposited on a substrate according to one embodiment of the invention;

FIG. 4B is a view similar to FIG. 4A, showing a photo-resist deposited on a substrate that is exposed to a radiation through a mask;

FIG. 4C is a view similar to FIG. 4B, after photo-resist portions of high radiation exposure are selectively removed from substrate using a first chemistry;

FIG. 4D is a view similar to FIG. 4C, after photo-resist portions of low radiation exposure are selectively removed from substrate using a second chemistry.

FIG. 5A shows one embodiment of forming pattern features having multiplicity of sizes;

FIG. 5B is a view similar to FIG. 5A, after selectively removing exposed photo-resist portions of high radiation exposure and low radiation exposure from a substrate;

FIG. 6A shows another embodiment of forming pattern features having multiplicity of sizes;

FIG. 6B is a view similar to FIG. 6A, after selectively removing exposed photo-resist portions of high radiation exposure and low radiation exposure from a substrate;

FIG. 7A shows forming an image with an intermediate intensity on a photo-resist on a substrate according to another embodiment of the invention;

FIG. 7B is a view similar to FIG. 7A, after selectively removing exposed photo-resist portions of high radiation exposure and low radiation exposure from a substrate;

FIG. 8A shows forming an image with an intermediate intensity on a photo-resist on a substrate according to another embodiment of the invention;

FIG. 8B is a view similar to FIG. 8A, after selectively removing exposed photo-resist portion of high radiation exposure and low radiation exposure from a substrate;

FIG. 9A shows a top view of one embodiment of photo-resist deposited on a substrate (not shown);

FIG. 9B is a view similar to FIG. 9A that shows a mask placed over photo-resist;

FIG. 9C is a view similar to FIG. 9B, after exposing the photo-resist to the radiation through a mask;

FIG. 9D is a view similar to FIG. 9C that illustrates exposing of residual portions to additional radiation through another mask;

FIG. 9E is a view similar to FIG. 9D, after selectively removing of photo-resist portions of high radiation exposure and low radiation exposure while leaving portions of the intermediate radiation exposure on a substrate intact.

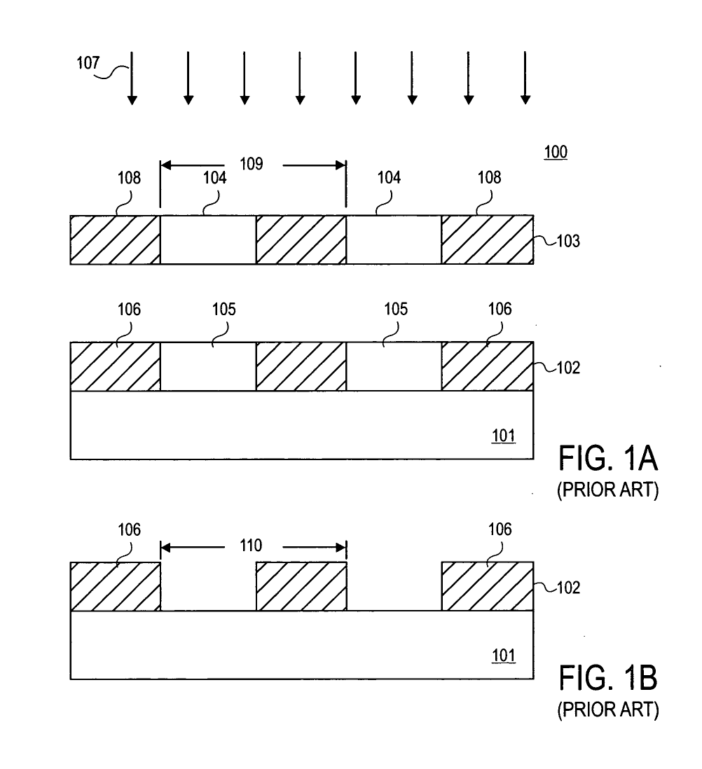

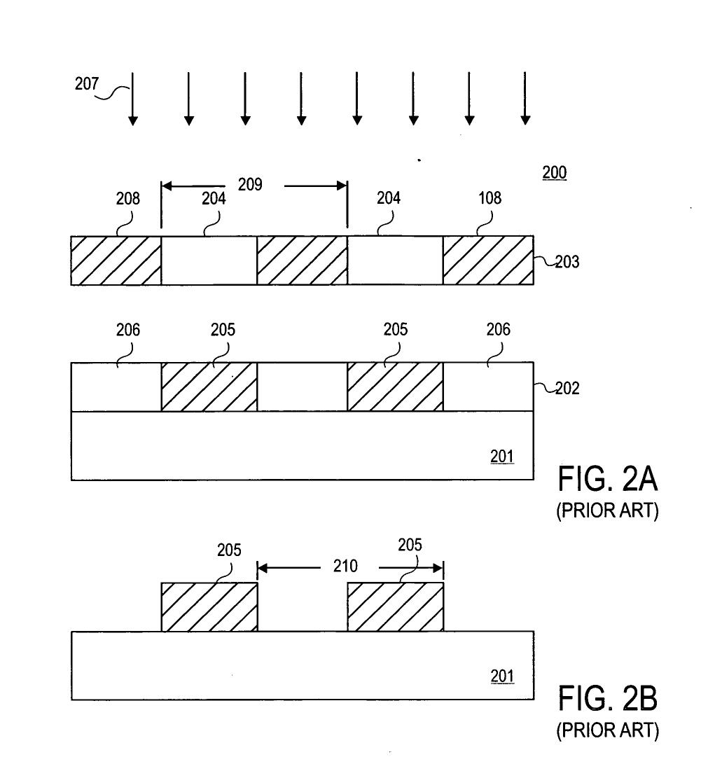

### DETAILED DESCRIPTION

In the following description, numerous specific details, such as specific materials, dimensions of the elements, processing conditions, e.g., temperature, pressure, time, and wavelengths, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

Methods to reduce the minimum pitch of a pattern that can be transferred onto a substrate for a given lithographic tool and mask are described herein. Multiple chemical treatments on exposed photo-sensitive materials, e.g., photo-resists, are used to achieve two times smaller lithographic pitch.

A photo-resist on a substrate is exposed to a radiation through a mask. The mask has features that are separated by a distance. Photo-resist portions having a first exposure to the radiation, second exposure to the radiation, and third exposure to the radiation are created. The photo-resist portions having the first exposure to the radiation are selectively removed from the substrate using a first chemistry. The second photo-resist portions having the second exposure to the radiation are selectively removed from the substrate using a second chemistry. The photo-resist portions having the third exposure to the radiation remain on the substrate to form a pattern having features. The distance between features of the pattern formed on the substrate is at least twice smaller than the distance between the features of the mask.

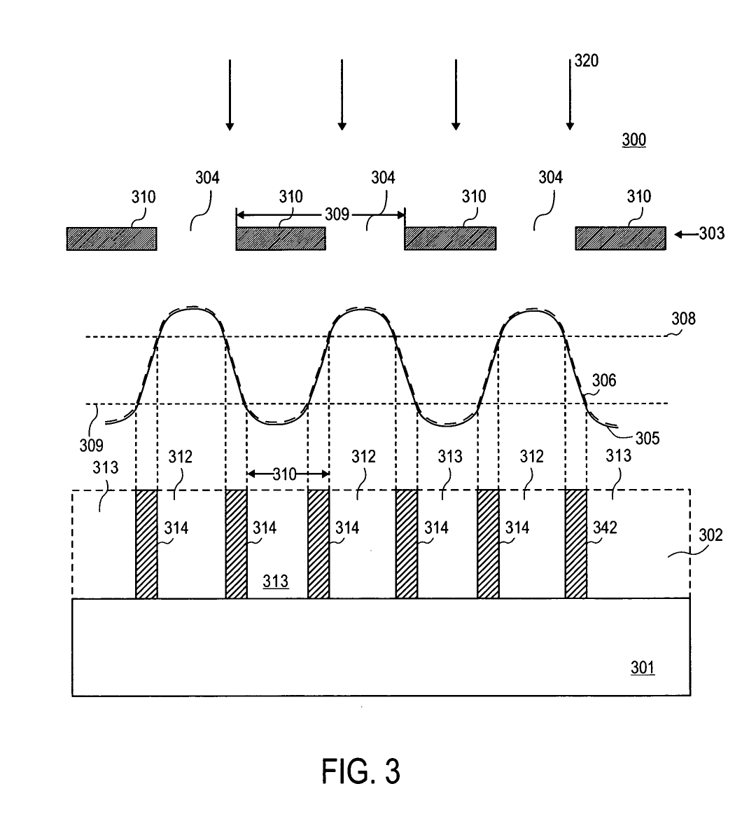

FIG. 3 shows a pattern transferred from a mask onto a substrate according to one embodiment of the invention. A photo-resist 302 deposited on a substrate 301 is exposed to a radiation 320 from a radiation source of a lithography system (not shown) using a mask 303. Mask 303 has opaque features 310 that are periodically spaced at a (“pitch”) 309 and clear portions 304, as shown in FIG. 3. For one embodiment, photo-resist 302 is a positive tone photo-resist. For another embodiment, photo-resist 302 is a negative tone photo-resist. Photo-resist 302 may be formed on substrate 301 for example, by spin coating followed by a pre-exposure bake, typically at temperatures between 90-150C for 60 to 120 seconds. Depositing a photo-resist on a substrate is known to one of ordinary skill in the art of the microelectronic device manufacturing. Light exposure causes chemical changes to photo-resist 302. Generally, a positive tone photoresist has polymers that become deprotected due to light exposure. In one embodiment, the light exposure causes the production of acid in the positive tone photoresist, and the acid changes the solubility of the positive tone photo-resist. That is, the solubility of the positive tone photoresist changes due to both light exposure and presence of the acid. For negative tone photoresist, light exposure results in cross-linking of polymer molecules that changes the solubility of the negative tone photo-resist. Negative tone photo-resists also may contain acids that affect the solubility of the negative tone photo-resist.

FIG. 3 shows a profile of radiation exposure 305 and a profile 306 of a response produced in photo-resist 302 by mask 303 and radiation 320 of the lithography system. As shown in FIG. 3, portions 312 that correspond to clear portions 304 receive high radiation exposure 320, portions 313 that correspond to opaque features 310 receive low radiation exposure 320, and portions 314 that correspond to edges of opaque features 310 receive intermediate radiation exposure 320. As shown in FIG. 3, profile 306 of portions 315 of photoresist 302 is higher than upper threshold 308, profile 306 of portions 313 is lower than lower threshold 309, and profile 306 of portions 314 is between lower threshold 309 and higher threshold 308.

In one embodiment, profile 306 is a chemical concentration of deprotected polymers in the positive tone photoresist 302 that is proportional to radiation exposure 305, as shown in FIG. 3. In another embodiment, profile 306 is an acid concentration in the photo-resist 302 that is proportional to radiation exposure. In another embodiment, for negative tone photo-resist 302, profile 306 is a concentration of cross-linked polymers that is proportional to radiation exposure 305, as shown in FIG. 3. In another embodiment, profile 306 is an average polymer molecule weight in negative tone photoresist 302 that is proportional to radiation exposure 305, as shown in FIG. 3.

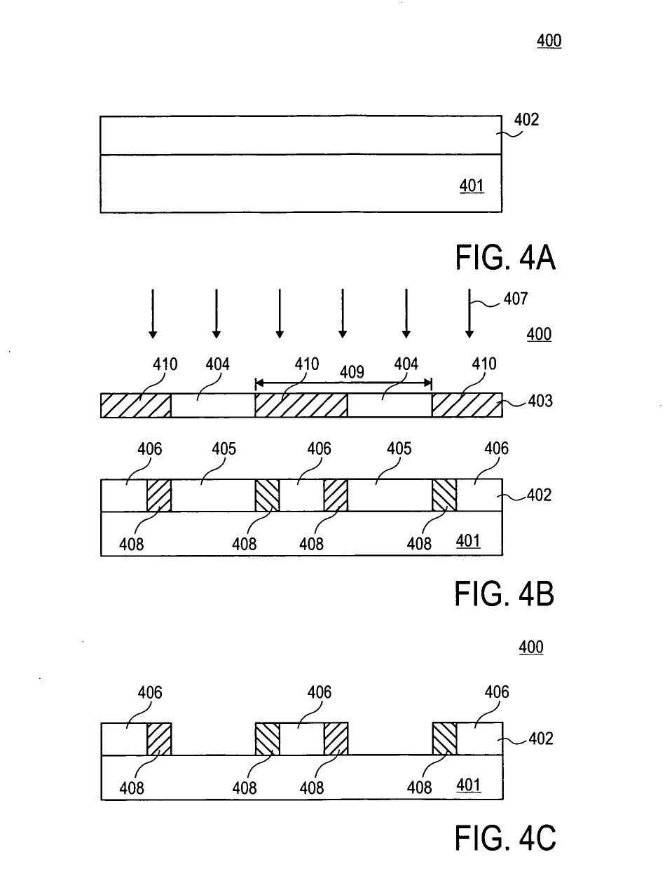

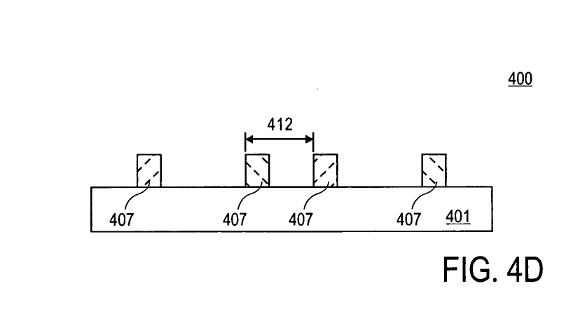

In one embodiment, upper threshold 308 corresponds to a first threshold of solubility of photoresist 302 when a first chemistry is applied to the photoresist. In one embodiment, lower threshold 308 corresponds to a second threshold of solubility of photoresist 302 when a second chemistry is applied to the photoresist, as described in further detail below. In one embodiment, portions 312 of the photo-resist 302 that correspond to clear portions 304 that have high radiation exposure 305 are selectively removed from substrate 301 using a first chemistry. Portions 313 of the photoresist 302 that have low radiation exposure 305 are selectively removed from substrate 301 using a second chemistry. Portions 314 that correspond to the edges of opaque features 310 that have intermediate exposure 320 remain on substrate 301 intact, as shown in FIG. 3.Selectively removing portions 312 and 313 of photoresist 302 using different chemistries while leaving portions 314 on substrate 301 intact is described in further detail below with respect to FIG. 4.

In one embodiment, for portions 312 of photo-resist 302, profile 306 of the concentration of acid in photo-resist 302 is higher than and upper threshold 308 of acid concentration. In one embodiment, upper threshold 308 of acid concentration is an acid level solubility threshold of photo-resist 302. For example, if acid concentration in positive tone photo-resist 302 is higher than the upper threshold 308 of acid concentration, the positive tone photo-resist becomes soluble when a first chemistry is applied, as described in further detail below with respect to FIG. 4. In one embodiment, portions 313 of the photo-resist 302 that correspond to opaque features 310 that have low radiation exposure 305 have profile 306 of the acid concentration lower than lower threshold 309 of acid concentration, as shown in FIG. 3. In one embodiment, lower threshold 309 of acid concentration is another acid level solubility threshold of photo-resist 302. For example, if acid concentration in positive tone photo-resist 302 is lower than lower threshold 309 of acid concentration, the photo-resist becomes soluble when a second chemistry is applied, as described in further detail below with respect to FIG. 4. In one embodiment, positive tone photoresist 302 has the upper acid concentration threshold in the approximate range of 30%-60% of the clear field acid level and the lower acid concentration threshold in the approximate range of 10-25% of the clear field acid concentration. In one embodiment, the clear field acid concentration is defined as the acid level of the photoresist completely exposed to radiation. In another embodiment, the clear field acid concentration is defined as the acid concentration when all the PAG (PhotoAcid Generation) material has reacted with radiation to produce acid species. Because of diffraction of light 320 from the edges of features 310, portions 314 of intermediate radiation exposure are created, as shown in FIG. 4. In one embodiment, portions 314 of the photo-resist 302 that have intermediate radiation exposure 305 have acid concentration between the upper acid concentration threshold and the lower acid concentration threshold 309. Portions 312 of high exposure to the radiation are selectively removed from the substrate using a first chemistry, as described in further detail below with respect to FIG. 4. Portions 313 of low exposure to the radiation are selectively removed from the substrate using a second chemistry, as described in further detail below with respect to FIG. 4. Portions 314 of intermediate exposure to the radiation remain on substrate 301 to form a pattern transferred by mask 303 and the lithography system.

As shown in FIG. 3, two photo-resist features (portions 314) are produced for every one mask feature 310, thereby doubling the amount of the pattern features on substrate 301. As a result, distance (“pitch”) 310 between the center of photo-resist features (portions 314 of intermediate exposure) becomes twice as small as the distance 310 between features 310 of the mask 303, as shown in FIG. 3.

FIG. 4A shows a photo-resist 402 deposited on substrate 401 according to one embodiment of the invention. In one embodiment, substrate 401 includes a semiconductor, e.g., a monocrystalline silicon, germanium, and any other semiconductor. In alternate embodiments, substrate 401 comprises any material to make any of integrated circuits, passive (e.g., capacitors, inductors) and active (e.g., transistors, photodetectors, lasers, diodes) microelectronic devices. Substrate 401 may include insulating materials that separate such active and passive microelectronic devices from a conductive layer or layers that are formed on top of them. In one embodiment, substrate 401 is a p-type monocrystalline silicon (“Si”) substrate that includes one or more insulating layers e.g., silicon dioxide, silicon nitride, sapphire, and other insulating materials. Photo-resist 402 may be formed on substrate 401 by spin coating. In one embodiment, photo-resist 402 is formed on substrate 401 to the thickness in the approximate range of 0.001 microns (“um”) to 0.5 um. Depositing a photo-resist on a substrate is known to one of ordinary skill in the art of the microelectronic device manufacturing. Next, photo-resist 402 is baked to solidify the photo-resist material onto substrate 401. In one embodiment, photo-resist 402 on substrate 401 is baked at a temperature in the approximate range of 90° C. to 180° C. for approximately 50-120 seconds.

In one embodiment, photo-resist 402 is a positive tone photo-resist. In another embodiment, photo-resist 402 is a negative tone photo-resist. In one embodiment, photo-resist 402 is an Extreme Ultraviolet Lithography (“EUVL”) photo-resist. In one embodiment, photo-resist 402 includes fluoropolymers. In another embodiment, photo-resist 402 includes silicon-containing polymers. In one embodiment, photo-resist 402 includes hydroxy styrene and/or acrylic acid monomers to provide acid groups when photo-resist is exposed to radiation. Generally, the choice of the material for photo-resist 402 depends on a particular microelectronic device processing application. For example, the choice of the material for photo-resist 402 depends on the transmission properties of the photo-resist at a given wavelength of radiation. In alternate embodiments, photo-resist 402 is optimized to a wavelength of radiation, e.g., 365 nm, 248 nm, 193 nm, 157 nm, and 13 nm. In one embodiment, photo-resist 402 is a 193 nm photo-resist, e.g., PARXXX supplied by Sumitomo Chemical, Co., Japan, ARXXXJN and ARXXXXJ supplied by JSR Co, Japan. In another embodiment, photo-resist 402 is a 248 nm photo-resist that includes apex-e from Rohm and Haas Electronic Materials, USA formerly known as Shipley Co. TOKXXX from Tokyo Ohka Kogyo (TOK), Co., Japan. In another embodiment, photo-resist 402 is a 248 nm photo-resist and a 13 nm photo-resist.

FIG. 4B is a view similar to FIG. 4A, showing a photo-resist deposited on a substrate that is exposed to a radiation through a mask. As shown in FIG. 4B, mask 403 has opaque features 410 that prevent the radiation 407 from being transmitted to photo-resist 402 and clear portions 404 that transmit the radiation to photo-resist 402. In one embodiment, mask 403 is an EUV mask. Typically, because extreme ultraviolet radiation is absorbed in almost all materials, a mask used in the EUVL is a reflective mask. The reflective mask, to transfer a pattern onto the wafer, reflects the radiation in certain regions and absorbs the radiation in other regions of the mask. Typical EUVL reflective mask blank includes a mirror deposited on a substrate, wherein the mirror consists of alternating layers of silicon and molybdenum, to maximize reflectivity of the light. The mirror of the EUVL mask blank is coated with a layer of an absorbing material. The absorbing material is patterned in a specific way to produce an EUVL mask. EUVL masks are known to one of ordinary skill in the art of microelectronic device manufacturing.

In one embodiment, mask 403 is a binary mask or chrome on glass mask. In another embodiment, mask 403 is an alternating phase shift mask. The alternating phase shift mask has portions etched to create a half-wavelength phase difference between adjacent portions (apertures) of the mask. In yet another embodiment, mask 403 is an embedded phase shift mask (also known as an attenuated phase shift mask or a half-tone phase shift mask) where a film is used to create a half-wavelength phase difference as well as a transmissions difference between light that passes through the film and light that only passes through clear regions on the mask substrate.

Radiation (“light”) 407 is provided from a radiation source of a lithography system (not shown) that can be any stepper or scanner known to one of ordinary skill in the art of microelectronic device manufacturing. The lithography system can be any type system using, for example, 365 nm, 248 nm, 193 nm, 157 nm, and 13 nm wavelengths of radiation. Mask 403 can be illuminated, for example, with normal incident light and off-axis illumination light, such as annular illumination, quadrupole illumination, and dipole illumination. These methods of illumination and exposing the photoresist to the light using the mask are known to one of ordinary skill in the art of microelectronic device manufacturing.

As shown in FIG. 4, radiation 407 that transmits using mask 403 forms one or more portions 405, one or more portions 406, and one or more portions 408 in photo-resist 402. As shown in FIG. 4A, portions 406 that correspond to opaque features 410 of mask 403 have low exposure to radiation 407, portions 405 that correspond to clear portions 404 of mask 403 have high exposure to radiation 407, and portions 408 that correspond to edges of opaque features 410 of mask 403 have an intermediate exposure to radiation 407. Portions 408 of intermediate radiation exposure are created because of diffraction of radiation 407 from the edges of features 410. In one embodiment, if 100% of incident radiation 407 is transmitted to photo-resist 402 using mask 403, radiation exposure of photo-resist 402 is 1, if 0% of incident radiation 407 is transmitted to photo-resist 402, exposure of photo-resist 402 is 0. In one embodiment, photo-resist portions 405 of high radiation exposure receive about 0.5 (50%) or more of an incident radiation 407, photo-resist portions 406 of low radiation exposure receive less than 0.15 (15%) of the incident radiation 407; and photo-resist portions 408 of intermediate radiation exposure receive between about 0.15 (15%) to about 0.5 (50%) of the incident radiation 407. In one embodiment, high exposure to radiation 407 increases the concentration of an acid in portions 405 of photo-resist 402 to a level higher than an upper acid concentration threshold. The upper concentration threshold is a first solubility threshold of photo-resist 402. In one embodiment, when the concentration of the acid in portions 405 of the positive tone photoresist 402 increases to a level higher than the first threshold of solubility of the photoresist (e.g., acid concentration threshold), positive tone photo-resist portions 405 become soluble when a first chemistry is applied, as described in further detail below. In another embodiment, when the chemical concentration of deprotected polymers in portions 405 of the positive tone photoresist 402 increases to a level higher than the first threshold of solubility of the photoresist (e.g., acid concentration threshold), positive tone photo-resist portions 405 become soluble when a first chemistry is applied, as described in further detail below. In yet another embodiment, when the concentration of cross-linked polymers in portions 405 in negative tone photoresist 402 increases to a level higher than the first threshold of solubility of the photoresist, negative tone photoresist portions 405 become soluble when the first chemistry is applied, as described in further detail below. In yet another embodiment, when the average polymer molecule weight in portions 405 in negative tone photoresist 402 increases to a level higher than the first threshold of solubility of the photoresist, negative tone photoresist portions 405 become soluble when the first chemistry is applied, as described in further detail below.

In low radiation exposure portions 406 of positive-tone photo-resist 402 concentration of an acid and/or chemical concentration of deprotected polymers is less than a lower threshold of solubility of the photoresist (e.g., acid concentration threshold). The positive tone photo-resist portions 406 become soluble when a second chemistry is applied, as described in further detail below. In another embodiment, when the concentration of cross-linked polymers and/or average polymer molecule weight in portions 405 of negative tone photoresist 402 is lower than the second threshold of solubility of the photoresist, negative tone photoresist portions 402 become soluble when the first chemistry is applied, as described in further detail below.

Typically, the first solubility threshold and the second solubility threshold are determined by a material of the photo-resist. Intermediate radiation exposure photo-resist portions 408 have an acid concentration between about the first solubility threshold and the second solubility threshold. That is, intermediate radiation exposure photo-resist portions 408 are not soluble when each of the first chemistry and the second chemistry is applied to photo-resist 402. Next, exposed photo-resist 402 is baked to enhance photo-induced chemical changes. In one embodiment, exposed photo-resist 402 is baked at temperature in the approximate range of 60° C. to 150° C. for about 50-120 seconds.

FIG. 4C is a view similar to FIG. 4B, after photo-resist portions 405 of high radiation exposure are selectively removed from substrate 401 using a first chemistry. In one embodiment, the first chemistry to selectively remove portions 405 of positive tone photo-resist 402 includes a base, e.g., alkali, amines. In one embodiment, the first chemistry to selectively remove portions 405 of positive tone photo-resist 402 includes tetramethylammonium hydroxide (“TMAH”). In one embodiment, a wafer containing positive-tone photo-resist 402 on substrate 401 is immersed into a development solution containing the first chemistry to remove soluble portions 405 and then dried out. Developing of the photo-resist 402 in the development solution to remove soluble portions is known to one of ordinary skill in the art of microelectronic device manufacturing. In one embodiment, exposed positive tone EUV photo-resist 402 formed on semiconductor substrate 401 is developed in the liquid development solution, e.g., tetramethylammonium hydroxide (“TMAH”) and the like, for between about 50 seconds and 100 seconds at room temperature and pressure to selectively remove portions 405 of high-acid concentration. As shown in FIG. 4C, portions 406 of low radiation exposure and portions 408 of intermediate radiation exposure remain on substrate 401 after developing the photo-resist 402 using the first chemistry.

FIG. 4D is a view similar to FIG. 4C, after photo-resist portions 406 of low radiation exposure are selectively removed from substrate 401 using a second chemistry. In one embodiment, the second chemistry to selectively remove portions 406 of the positive tone photo-resist 402 from substrate 401 includes a supercritical solution (“fluid”), e.g., supercritical CO₂ solution (“sc CO₂”), and the like. Supercritical fluids have unique properties, such as high diffusivities comparable to those of gases, liquid-like densities that can be controlled by manipulating pressure and temperature conditions. Generally, supercritical solution development involves placing the photo-resist in a high pressure chamber with a supercritical fluid where the pressure and temperature adjusted to achieve best performance. The supercritical fluids may contain other materials to improve the development process. For example, scCO₂ solutions may contain CO₂ compatible salts (“CCS”) complexes. CO₂ compatible salts complexes are, for example, all ammonium salts of the general formula L₃RN⁺X⁻, where at least one L contains CO₂ compatible groups such as siloxane or fluoroalkyl groups, R is a short chain (C₆ or lower) hydrocarbon, and X is an anion selected from the group of iodides, hydroxides, and carboxylates. In one embodiment, CCS complex is L₃MeN⁺C⁻ (A) that includes a non-symmetrical cation and a carboxylate anion. Other materials besides salts, e.g., ethanol, can be mixed with CO₂. In one embodiment, a wafer containing photo-resist 402 on substrate 401 is placed into a photo-resist developing chamber (not shown). The photo-resist developing chamber is brought up to pressure. Generally, by changing the pressure in the chamber one can control the type and amount of gases that enter the chamber. A gas, e.g., carbon dioxide, enters the chamber under the pressure. To catalyze chemical reactions during the development process, other materials, e.g., CO₂ compatible salts, may be added to the gas. These materials may be either added into the chamber before or together with the gas. In one embodiment, positive tone photo-resist 402 on substrate 401 is developed in supercritical CO₂ solutions using CO₂ compatible salts to remove portions 406 from substrate 401. In one embodiment, CO₂ compatible salts are added to the chamber containing a wafer with photo-resist 402 on substrate 401 at ambient conditions, then CO₂ gas is added under a predetermined pressure, e.g., 4000 psi, to the chamber. CCS dissolves instantly upon addition of CO₂ under a predetermined pressure to form supercritical CO₂ solution. In one embodiment, the concentration of CCS in CO₂ is between about 1 millimole (“mM”) to about 20 mM. Typically, supercritical CO₂ solution acts like a liquid during developing of photo-resist 402 to remove portions 406. After developing of photo-resist 402 for a predetermined time, e.g., 3 minute, supercritical CO₂ solution is depressured to become a CO₂ gas again. The chamber is flushed with pure CO₂ to remove the products of chemical interactions between the photo-resist 402 and sc CO₂ away from substrate 401. In one embodiment, developing of the positive tone photo-resist 402 to remove portions 406 from substrate 401 of monocrystalline silicon in supercritical CO₂ solutions using CO₂ compatible salts is performed when the pressure in the chamber is in the approximate range of 2000 psi to 8000 psi and the temperature is in the approximate range of 40° C. to 100° C. The developing time can be from about 1 minute to about 10 minutes. In another embodiment, developing of the positive tone photo-resist 402 to remove portions 406 from substrate 401 of monocrystalline silicon in supercritical CO₂ solutions using CO₂ compatible salts is performed for about 3 minutes when the pressure in the chamber is in about 4000 psi and the temperature is about 50° C.

In another embodiment, the first chemistry to remove high exposure portions 405 of negative tone photo-resist 402, includes sc CO₂ solution. The sc CO₂ solution containing CO₂ compatible salts may be applied to the negative photo-resist in a manner similar to described above with respect to the positive photo-resist. In another embodiment, the second chemistry to selectively remove low exposure portions 406 of negative tone photo-resist 402 includes a base, e.g., alkali, amines. In another embodiment, the second chemistry to remove low exposure portions 406 of negative tone photoresist 402, includes TMAH. Developing low exposure portions of the negative tone photo-resist is known to one of ordinary skill in the art of microelectronic device manufacturing.

As shown in FIG. 4D, the photo-resist portions of high exposure and the photo-resist portions of low exposure are selectively removed, so that only photo-resist portions 407 of intermediate exposure remain on substrate 401.

Because an image of each of mask feature has two transitions regions that go from low to high light intensity, the resulting resist pattern would have twice the number of features than the mask pattern. As shown in FIG. 4D, for every one light intensity swing between opaque features 410 and clear portions 404 of mask 403 two photo-resist features (portions 407) are produced.

Pitch 412 between portions 407 is at least twice less than pitch 410 between features 410 of mask 403, as shown in FIG. 4D. In one embodiment, pitch 412 between portions 407 of intermediate light intensity is in the approximate range 5 nm to 30 nm. The order of these two development processes to selectively remove portions 405 of high radiation exposure using the first chemistry and to selectively remove portions of 406 of low radiation exposure using the second chemistry, as described above with respect to FIGS. 4C and 4D, could be switched without changing the resulting pattern. In one embodiment, portions 405 of high radiation exposure are selectively removed from substrate 401 before removing portions 406 of low radiation exposure from substrate 401. In another embodiment, portions 405 of high radiation exposure are selectively removed from substrate 401 after removing portions 406 of low radiation exposure from substrate 401.

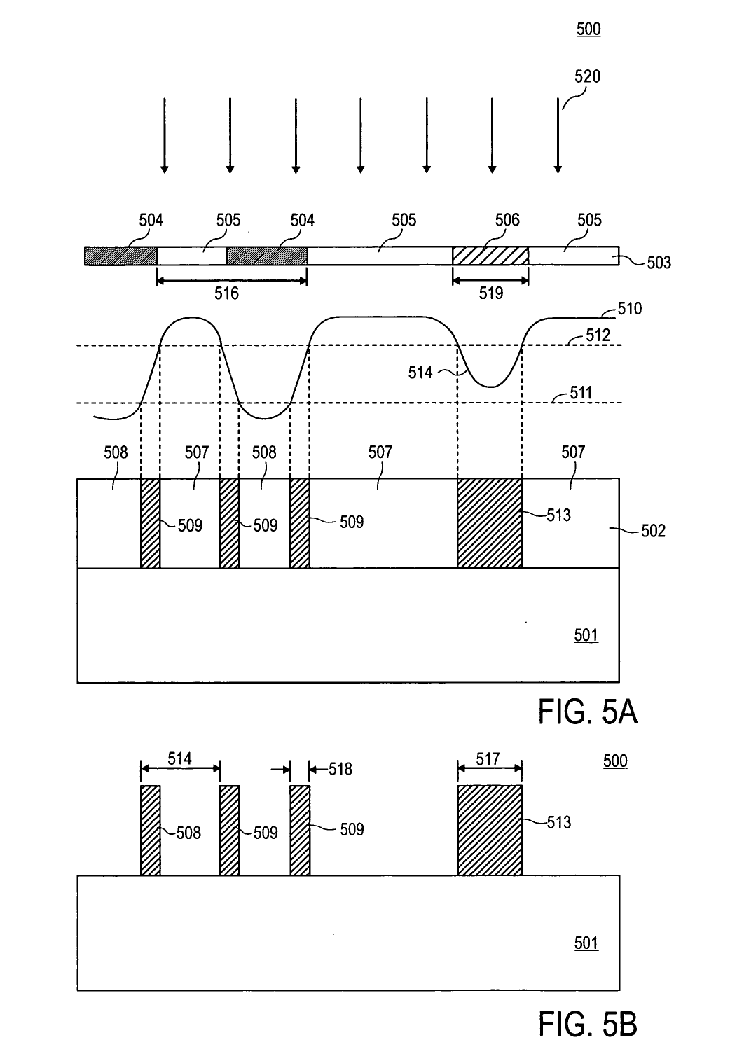

FIGS. 5A-5B show one embodiment of forming pattern features having multiplicity of sizes. FIG. 5A shows forming an image with an intermediate intensity on a photo-resist on a substrate using a mask with an intermediate transmission feature according to one embodiment of the invention. As shown in FIG. 5A, mask 503 has opaque features 504, clear portions 505, and a feature of intermediate transmission 506 among clear portions 505. A profile 510 of radiation exposure produced in photo-resist 502 on substrate 501 by mask 503 and radiation 520 of the lithography system is shown in FIG. 5A. Portions 507 of the positive tone photo-resist 502 that correspond to clear portions 505 that correspond to high radiation exposure have higher acid concentration and/or chemical concentration of deprotected polymers than first threshold 512, as shown in FIG. 5A. Portions 508 of the positive tone photo-resist 502 that correspond to opaque features 504 that have low radiation exposure have the acid concentration and/or chemical concentration of deprotected polymers lower than second threshold 511, as shown in FIG. 5A. Portions 509 of the photo-resist 502 that correspond to edges of opaque features 504 and portion 513 of photo-resist 502 that correspond to intermediate transmission feature 506 have intermediate radiation exposure and have the acid concentration and/or chemical concentration of deprotected polymers between first threshold 512 and second threshold 511, as shown in FIG. 5A. First and second thresholds 512 and 511 are described with respect to FIGS. 3 and 4.

In one embodiment, intermediate transmission mask feature 506 includes a material that transmits only a portion of the incident radiation 520, such that radiation exposure of portion 513 is between about 0.15 to about 0.5 of incident radiation 520. Such materials are known to one of ordinary skill in the art of microelectronic device manufacturing. In one embodiment, photo-resist portions 507 of high radiation exposure receive about 0.5 or more of an incident radiation 520, photo-resist portions 508 of low radiation exposure receive less than 0.15 of the incident radiation 520; and photo-resist portions 509 and 513 of intermediate radiation exposure receive between about 0.15 to about 0.5 of the incident radiation 520. Next, exposed photo-resist 502 is baked to enhance photo-induced chemical changes as described above with respect to FIGS. 3-4.

FIG. 5B is a view similar to FIG. 5A, after selectively removing exposed photo-resist portions 507 of high radiation exposure from substrate 501 using the first chemistry and selectively removing exposed photo-resist portions 508 of low radiation exposure from substrate 501 using second chemistry, as described above with respect to FIGS. 3 and 4. As shown in FIG. 5B, pattern features are created on substrate 501 from intermediate radiation exposure portions 509 by diffraction of the radiation at the edges of the mask features 504, as described above with respect to FIGS. 3 and 4, while the large feature is created on substrate 501 from intermediate radiation exposure portion 513 produced by intermediate transmission mask feature 506. As such, resist features having a multiplicity of sizes can be patterned on substrate 501.

As shown in FIG. 5B, pitch 514 between portions 509 is at least twice smaller than pitch 516 between features 504. In one embodiment, pitch 514 is between about 20 nm to about 80 nm. In one embodiment, size 517 of the portion 513 is modulated by varying the size 519 of the intermediate transmission feature 506 of mask 503. In one embodiment, the size 518 of the portions 509 is less than 30 nm, and the size 517 of portion 513 is at least 40 nm.

One of ordinary skill in the art of microelectronic device manufacturing will appreciate that method described above with respect to FIGS. 5A-5B may be used in a similar manner with a negative tone photoresist, using the first chemistry and the second chemistry as described above with respect to FIG. 4.

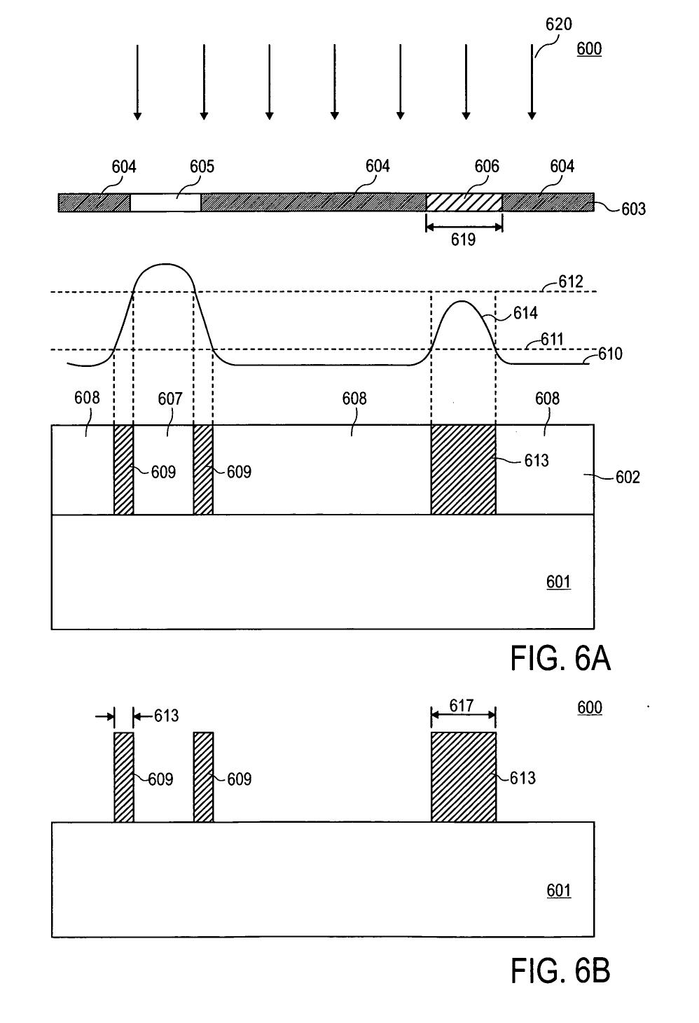

FIGS. 6A-6B show another embodiment of forming pattern features having multiplicity of sizes. FIG. 6A shows forming an image with an intermediate intensity on a photo-resist on a substrate using a mask with an intermediate transmission feature according to another embodiment of the invention. As shown in FIG. 5A, mask 603 has opaque features 604, clear portions 605, and an intermediate transmission region 606 among opaque features 604. A profile 610 of radiation exposure and acid concentration produced in photo-resist 602 on substrate 601 by mask 603 and radiation 620 of the lithography system is shown in FIG. 6A. Portions 607 of the positive tone photo-resist 602 that correspond to clear portions 605 that correspond to high radiation exposure have higher acid concentration and/or chemical concentration of deprotected polymers than a first threshold 612, as shown in FIG. 6A. Portions 608 of the positive tone photo-resist 602 that correspond to opaque features 604 that have low radiation exposure have the acid concentration and/or chemical concentration of deprotected polymers lower than a second acid concentration threshold 611, as shown in FIG. 6A. Portions 609 of the positive tone photo-resist 602 that correspond to edges of opaque features 604 and portion 613 of photo-resist 602 that correspond to intermediate transmission feature 606 have intermediate radiation exposure and have the acid concentration and/or chemical concentration of deprotected polymers between first threshold 612 and second threshold 611, as shown in FIG. 6A. First and second thresholds 612 and 611 are described with respect to FIGS. 3 and 4.

As shown in FIG. 6A, intermediate radiation exposure is created in portions 609 by diffraction of the radiation 620 at the edges mask features 604, and in portion 613 by intermediate transmission mask feature 606. In one embodiment, intermediate transmission mask feature 606 includes a material that transmits only a portion of the incident radiation 620, such that radiation exposure of portion 613 is between about 0.15 to about 0.5 of incident radiation 620. Such materials are known to one of ordinary skill in the art of microelectronic device manufacturing. In one embodiment, photo-resist portions 607 of high radiation exposure receive about 0.5 or more of an incident radiation 620, photo-resist portions 608 of low radiation exposure receive less than 0.15 of the incident radiation 620; and photo-resist portions 609 and 613 of intermediate radiation exposure receive between about 0.15 to about 0.5 of the incident radiation 620. Next, exposed photo-resist 602 is baked to enhance photo-induced chemical changes as described above with respect to FIGS. 3-4.

FIG. 6B is a view similar to FIG. 6A, after selectively removing exposed photo-resist portions 607 of high radiation exposure from substrate 601 using the first chemistry and selectively removing exposed photo-resist portions 608 of low radiation exposure from substrate 601 using the second chemistry, as described above with respect to FIGS. 3 and 4. As shown in FIG. 6B, pattern features are created on substrate 601 from intermediate radiation exposure portions 609 by diffraction of the radiation at the edges of the mask features 604, as described above with respect to FIGS. 3 and 4, while the large feature is created on substrate 601 from intermediate radiation exposure portion 613 produced by intermediate transmission mask feature 606. As such, resist features having a multiplicity of sizes can be patterned on substrate 601. Size 617 of portion 613 can be modulated by varying size 619 of intermediate transmission feature 606 of mask 603. In one embodiment, the size 618 of portions 609 is less than 30 nm, and the size 617 of portion 613 is at least 40 nm.

One of ordinary skill in the art of microelectronic device manufacturing will appreciate that method described above with respect to FIGS. 6A-6B may be used in a similar manner with a negative tone photoresist, using the first chemistry and the second chemistry as described above with respect to FIG. 4.

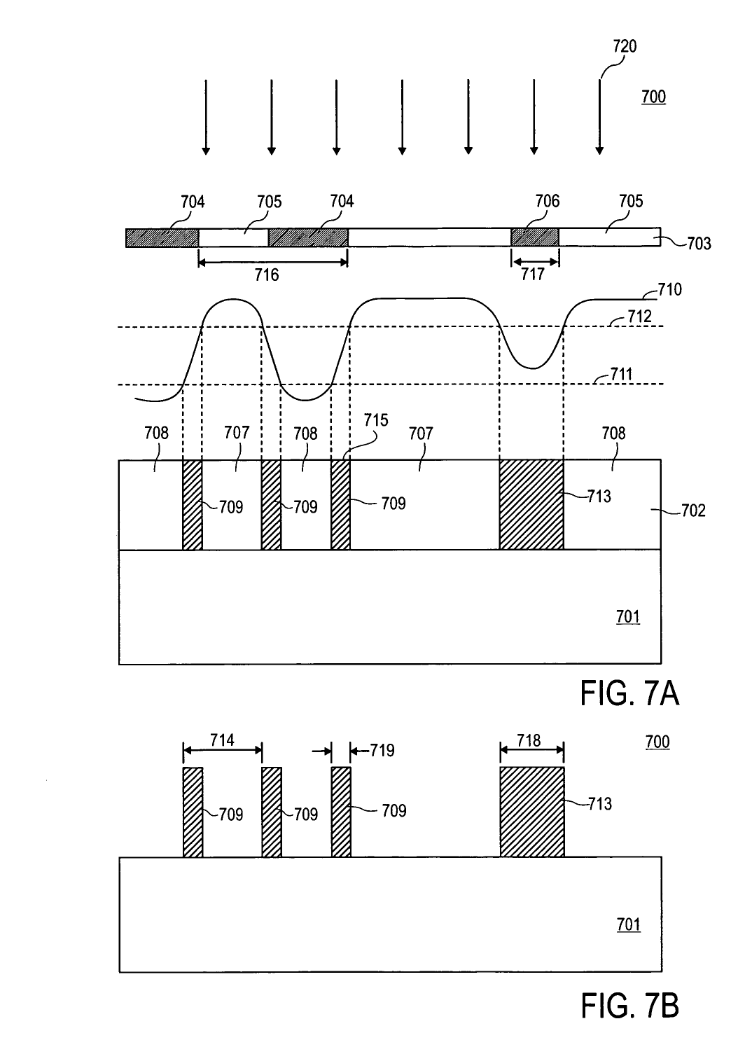

FIGS. 7A-7B show yet another embodiment of forming pattern features having multiplicity of sizes. FIG. 7A shows forming an image with an intermediate intensity on a photo-resist on a substrate according to yet another embodiment of the invention. As shown in FIG. 7A, mask 703 has opaque features 704, clear portions 705, and a opaque feature 706 placed among clear portions 705. Opaque feature 706 has a width 717 small enough to render intermediate radiation exposure to portion 713 of photo-resist 702 by diffraction of the radiation 720 from the edges of feature 706. A profile 710 of radiation exposure and acid concentration and/or chemical concentration of deprotected polymers produced in photo-resist 702 on substrate 701 by mask 703 and radiation 720 of a lithography system is shown in FIG. 7A. Portions 707 of the photo-resist 702 that correspond to clear portions 705 that receive high radiation exposure have higher acid concentration and/or chemical concentration of deprotected polymers than first threshold 712, as shown in FIG. 7A. Portions 708 of the photo-resist 702 that correspond to opaque features 704 that receive low radiation exposure have the acid concentration and/or chemical concentration of deprotected polymers lower than second threshold 711, as shown in FIG. 7A. Portions 709 of the photo-resist 702 that correspond to edges of opaque features 704 and portion 713 of photo-resist 702 that correspond to opaque feature 707 have intermediate radiation exposure and have the acid concentration and/or chemical concentration of deprotected polymers between first threshold 712 and second concentration threshold 711, as shown in FIG. 7A. First and second thresholds 712 and 711 are described with respect to FIGS. 3 and 4. As shown in FIG. 7A, intermediate radiation exposure is created in portions 709 and 713 by diffraction of the radiation 720 at the edges mask features 704 and at the edges of mask feature 706 respectively. In one embodiment, photo-resist portions 707 of high radiation exposure receive about 0.5 or more of an incident radiation 720, photo-resist portions 708 of low radiation exposure receive less than 0.15 of the incident radiation 720; and photo-resist portions 709 and 713 of intermediate radiation exposure receive between about 0.15 to about 0.5 of the incident radiation 720. Next, exposed photo-resist 702 is baked to enhance photo-induced chemical changes as described above with respect to FIGS. 3-4.

FIG. 7B is a view similar to FIG. 7A, after selectively removing exposed photo-resist portions 707 of high radiation exposure from substrate 701 using the first chemistry and selectively removing exposed photo-resist portions 708 of low radiation exposure from substrate 701 using second chemistry, as described above with respect to FIGS. 3 and 4. As shown in FIG. 7B, pattern features are created on substrate 701 from intermediate radiation exposure portions 709 and 713 by diffraction of the radiation at the edges of the mask features 704 and 706 respectively. As shown in FIG. 7B, pitch 714 between portions 709 is at least twice smaller than pitch 716 between features 704. In one embodiment, pitch 714 is between about 20 nm to about 80 nm. In one embodiment, size 718 of the portion 713 is modulated by varying the size 717 of the opaque feature 706.

One of ordinary skill in the art of microelectronic device manufacturing will appreciate that method described above with respect to FIGS. 7A-7B may be used in a similar manner with a negative tone photoresist, using the first chemistry and the second chemistry as described above with respect to FIG. 4.

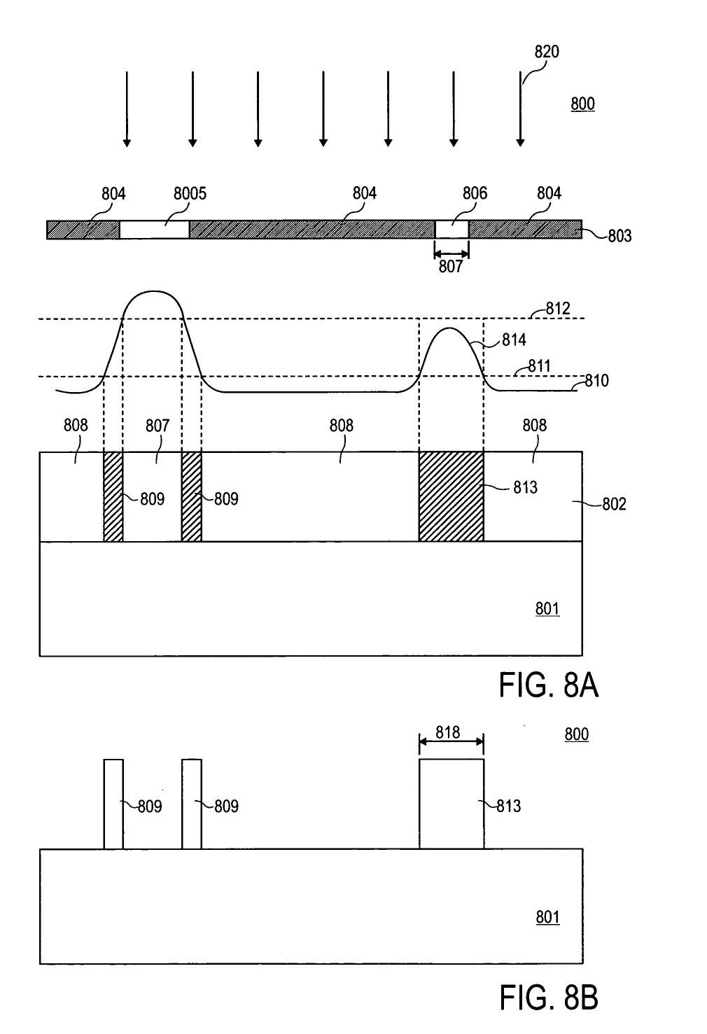

FIGS. 8A-7B show yet another embodiment of forming pattern features having multiplicity of sizes. FIG. 8A shows forming an image with an intermediate intensity on a photo-resist on a substrate according to yet another embodiment of the invention. As shown in FIG. 7A, mask 803 has opaque portions 804, clear feature 805, and a clear feature 806 placed among opaque portions 804. Clear feature 806 has a width 817 small enough to render intermediate radiation exposure to portion 813 of photo-resist 802 by diffraction of the radiation 820 from the edges of feature 806. A profile 810 of radiation exposure and acid concentration and/or chemical concentration of deprotected polymers produced in photo-resist 802 on substrate 801 by mask 803 and radiation 820 of a lithography system is shown in FIG. 8A. Portion 807 of the photo-resist 802 that correspond to clear feature 805 that receives high radiation exposure has higher acid concentration and/or chemical concentration of deprotected polymers than first threshold 812, as shown in FIG. 8A. Portions 808 of the photo-resist 802 that correspond to opaque portions 804 that receive low radiation exposure have the acid concentration and/or chemical concentration of deprotected polymers lower than second threshold 811, as shown in FIG. 8A. Portions 809 of the photo-resist 802 that correspond to edges of opaque portions 804 and portion 813 of photo-resist 802 that correspond to clear feature 806 have intermediate radiation exposure and have the acid concentration and/or chemical concentration of deprotected polymers between first threshold 812 and second threshold 811, as shown in FIG. 8A. First and second thresholds 812 and 811 are described with respect to FIGS. 3 and 4. As shown in FIG. 8A, intermediate radiation exposure is created in portions 809 and 813 by diffraction of the radiation 820 at the edges mask feature 804 and at the edges of mask feature 806 respectively. In one embodiment, photo-resist portion 807 of high radiation exposure receives about 0.5 or more of an incident radiation 820, photo-resist portions 808 of low radiation exposure receive less than 0.15 of the incident radiation 820; and photo-resist portions 809 and 813 of intermediate radiation exposure receive between about 0.15 to about 0.5 of the incident radiation 820. Next, exposed photo-resist 802 is baked to enhance photo-induced chemical changes as described above with respect to FIGS. 3-4.

FIG. 8B is a view similar to FIG. 8A, after selectively removing exposed photo-resist portion 807 of high radiation exposure from substrate 801 using the first chemistry and selectively removing exposed photo-resist portions 808 of low radiation exposure from substrate 801 using second chemistry, as described above with respect to FIGS. 3 and 4. As shown in FIG. 8B, pattern features are created on substrate 801 from intermediate radiation exposure portions 809 and 813 by diffraction of the radiation at the edges of the mask features 804 and 806 respectively. Size 818 of the portion 813 can be modulated by varying the size 817 of the clear feature 806.

One of ordinary skill in the art of microelectronic device manufacturing will appreciate that method described above with respect to FIGS. 8A-8B may be used in a similar manner with a negative tone photoresist, using the first chemistry and the second chemistry as described above with respect to FIG. 4.

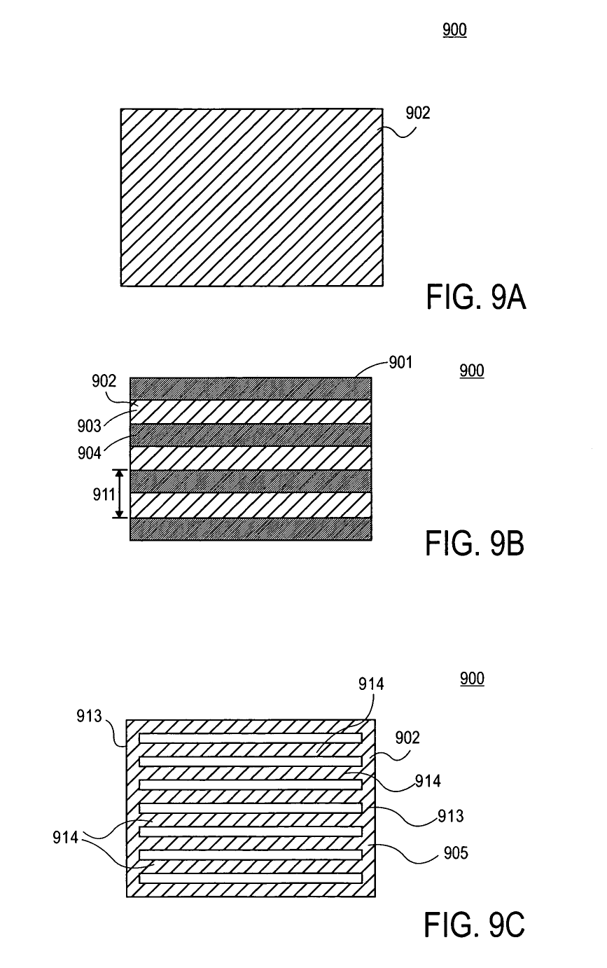

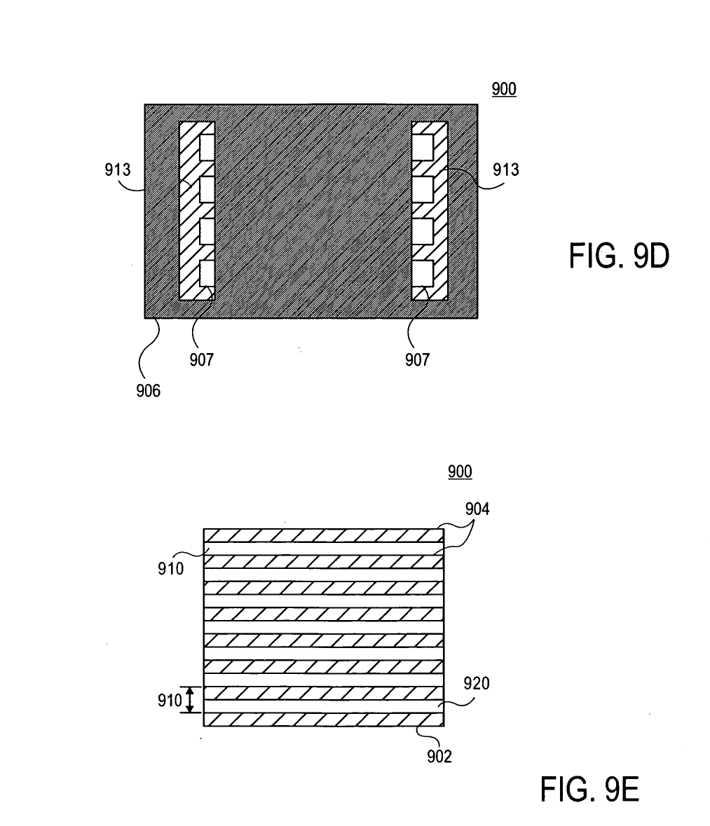

FIGS. 9A-9E show one embodiment of a method of using a second resist exposure prior to the development processes to remove residual photo-resist portions. FIG. 9A shows a top view of one embodiment of photo-resist 902 deposited on a substrate (not shown), as described above with respect to FIGS. 3-7. FIG. 9B is a view similar to FIG. 9A that shows a mask 901 placed above photo-resist 902, as described above with respect to FIGS. 3-7. Photo-resist 902 is exposed to the radiation (not shown) using mask 901 that includes opaque features 904 and clear portions 903 to produce portions of high radiation exposure, low radiation exposure, and intermediate radiation exposure as described above with respect to FIGS. 3-7.

FIG. 9C is a view similar to FIG. 9B, after exposing photo-resist 902 to the radiation using mask 901. As shown in FIG. 9C, photo-resist 902 has portions 905 of intermediate radiation exposure. As shown in FIG. 9C, portions 905 of intermediate radiation exposure include unwanted residual intermediate radiation exposure photo-resist portions 913 that are positioned at the edges of long intermediate radiation exposure portions 914 (pattern features). Portions 913 result from the diffraction of the radiation at the edges of the features 904 of mask 901.

FIG. 9D is a view similar to FIG. 9C that illustrates exposing of residual intermediate radiation exposure portions 913 to additional radiation through another mask 906. Mask 906 has clear features 907 to expose residual portions 913 to the additional radiation. Exposing residual portions 913 to the additional radiation through clear features 907 converts portions 913 to the high radiation exposure portions that have the acid concentration higher than the upper acid concentration threshold, as described above with respect to FIGS. 3-7. After exposing the photo-resist 902 to the radiation using mask 901 and mask 906, the photo-resist 902 is baked to enhance photo-induced chemical changes as described above with respect to FIGS. 3-4.

FIG. 9E is a view similar to FIG. 9D, after selectively removing of photo-resist portions of high radiation exposure using the first chemistry, and after selectively removing of photo-resist portions of low radiation exposure using the second chemistry while leaving portions of the intermediate radiation exposure on the substrate intact, as described above with respect to FIGS. 3-4. As shown in FIG. 9E, a pattern having a pitch 910 formed from portions 914 of intermediate radiation exposure remains on substrate 920. Pattern pitch 910 is at least twice less than pitch 911 between mask features 904, as shown in FIGS. 9B and 9E.

In the foregoing specification, the invention has been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A method, comprising:
exposing a photo-resist formed on a substrate to a radiation using a mask to form one or more first photo-resist portions, one or more second photo-resist portions, and one or more third photo-resist portions;
removing the one or more first photo-resist portions from the substrate using a first chemistry; and
removing the one or more second photo-resist portions from the substrate using a second chemistry.

2. The method of claim 1, wherein the third photo-resist portions remain on the substrate while the removing the first photo-resist portions and the removing the second photo-resist portions.

3. The method of claim 1, wherein the first chemistry includes a base.

4. The method of claim 1, wherein the second chemistry includes a supercritical solution.

5. The method of claim 1, wherein the photo-resist is a positive tone photo-resist.

6. The method of claim 1, wherein the photo-resist is a negative tone photo-resist.

7. The method of claim 1, wherein the first photo-resist portions are exposed to at least 50% of the radiation, the second photo-resist portions are exposed to less than 15% of the radiation, and the third photo-resist portions are exposed to between 15% and 50% of the radiation.

8. The method of claim 1, wherein the first photo-resist portions have an acid concentration higher than an upper acid concentration threshold, the second photo-resist portions have an acid concentration less than a lower acid concentration threshold, and the third photo-resist portions have an acid concentration between the upper acid concentration threshold and the lower acid concentration threshold.

9. A method to double pattern features, comprising:
exposing a photo-resist formed on a substrate to a first radiation through a first mask that has first features and an intermediate transmission region to form first photo-resist portions having a high radiation exposure, second photo-resist portions having a low radiation exposure, and third photo-resist portions having an intermediate radiation exposure;
removing the first photo-resist portions from the substrate using a first chemistry; and
removing the second photo-resist portions from the substrate using a second chemistry while third photo-resist portions remain on the substrate to form a first pattern having first features.

10. The method of claim 9, wherein an amount of the second features is at least twice larger than the amount of the first features.

11. The method of claim 10, wherein the first chemistry includes a base.

12. The method of claim 10, wherein the second chemistry includes a supercritical solution.

13. The method of claim 10, further comprising modulating a first size of at least one of the third portions by modulating a second size of the intermediate transmission region.

14. The method of claim 10, further comprising
exposing the photo-resist to a second radiation through a second mask to form a second pattern in the photo-resist.

15. The method of claim 10, wherein the photo-resist is a positive tone photo-resist.

16. A method to reduce a pattern pitch, comprising:
exposing a photo-resist on a substrate to a radiation using a mask to form one or more first photo-resist portions having a first acid concentration, one or more second photo-resist portions having a second acid concentration, and one or more third photo-resist portions having a third acid concentration;
developing the photo-resist using a first chemistry to selectively remove the first photo-resist portions;
developing the photo-resist using a second chemistry to selectively remove the second photo-resist portions.

17. The method of claim 16, wherein the first acid concentration is higher than an upper acid concentration threshold, the second acid concentration is less than a lower acid concentration threshold, and the third acid concentration is between the upper acid concentration threshold and the lower acid concentration threshold.

18. The method of claim 15, wherein first photo-resist portions are exposed to at least 50% of the radiation, the second photo-resist portions are exposed to less than 15% of the radiation; and the third photo-resist portions are exposed to between 15% and 50% of the radiation.

19. The method of claim 15, wherein the first chemistry includes a base.

20. The method of claim 15, wherein the second chemistry includes a supercritical solution.
